(19) United States
(12) Patent Application Publication
(10) Pub. No.: US 2024/0193756 A1
(43) Pub. Date: Jun. 13, 2024

(54) AUTOMATIC SEGMENTATION OF AN IMAGE OF A SEMICONDUCTOR SPECIMEN AND USAGE IN METROLOGY

(71) Applicant: Applied Materials Israel Ltd., Rehovot (IL)

(72) Inventors: Lior AKERMAN, Mazkeret Batya (IL); Tomer Haim PELED, Ness-Ziona (IL)

(21) Appl. No.: 18/537,693

(22) Filed: Dec. 12, 2023

(30) Foreign Application Priority Data
Dec. 12, 2022 (IL) 299017

(51) Int. Cl. G06T 7/00; G06T 7/11

(52) U.S. Cl. CPC G06T 7/0006; G06T 7/11; G06T 2207/10061; G06T 2207/20081; G06T 2207/30148

(57) ABSTRACT

There is provided a method and a system in which a processing circuitry is configured to obtain an inspection image representative of 2D information of an inspection area of a semiconductor specimen, and feed the inspection image to a trained machine learning model operative to segment the inspection image into at least a first segment S′₁ and a second segment S′₂, wherein the first segment S′₁ corresponds to a first region of the inspection area which has a height profile pattern corresponding to a first height profile pattern, and the second segment S′₂ corresponds to a second region of the area which has a height profile pattern corresponding to a second height profile pattern, wherein the first height profile pattern is different from the second height profile pattern.

### RELATED APPLICATIONS

This application claims the benefit of priority from Israeli Patent Application No. 299017, filed Dec. 12, 2022, which is incorporated herein by reference.

### TECHNICAL FIELD

The presently disclosed subject matter relates, in general, to the field of examination of a specimen, and more specifically, to automating the examination of a specimen.

### BACKGROUND

Current demands for high density and performance associated with ultra large-scale integration of fabricated devices require submicron features, increased transistor and circuit speeds, and improved reliability. Such demands require formation of device features with high precision and uniformity, which, in turn, necessitates careful monitoring of the fabrication process, including automated examination of the devices while they are still in the form of semiconductor wafers.

Examination processes are used at various steps during semiconductor fabrication to measure dimensions of the specimens (semiconductor metrology measurements), such as, for example, critical dimensions (CD) measurements.

### GENERAL DESCRIPTION

In accordance with certain aspects of the presently disclosed subject matter, there is provided a system comprising one or more processing circuitries configured to: obtain an inspection image representative of 2D information of an inspection area of a semiconductor specimen, and feed the inspection image to a trained machine learning model operative to segment the inspection image into at least a first segment S′₁ and a second segment S′2, wherein the first segment S′₁ corresponds to a first region of the inspection area which has a height profile pattern corresponding to a first height profile pattern, and the second segment S′₂ corresponds to a second region of the area which has a height profile pattern corresponding to a second height profile pattern, wherein the first height profile pattern is different from the second height profile pattern.

According to some embodiments, the first segment S′₁ corresponds to a first feature of a given structural element present in the inspection area, and the second segment S′₂ corresponds to a second different feature of the same given structural element.

According to some embodiments, the system is configured to, during run-time examination of the specimen, use the trained machine learning model to determine, in the inspection image, a plurality of segments corresponding to different features of interest of the same given structural element present in the inspection area.

According to some embodiments, the features of interest, or data informative thereof, have been used in training of the machine learning model.

According to some embodiments, for each given structural element of a plurality of structural elements present in the inspection area, the system is configured to use the trained machine learning model to determine segments of the inspection image corresponding to different features of interest of said given structural element, thereby obtaining a set of segments, and use the set of segments to determine metrology data informative of the plurality of the structural elements.

According to some embodiments, the trained machine learning model is operative to segment the inspection image representative of 2D information of the inspection area into a plurality of two-dimensional segments informative of different height profile patterns of the inspection area, without receiving 3D information on the inspection area.

According to some embodiments, the machine learning model has been trained using training images, wherein each training image has been segmented into a first segment S₁ corresponding to the first segment S′₁ of the inspection image and a second segment S₂ corresponding to the second segment S′₂ of the inspection image.

According to some embodiments, the machine learning model has been trained using data informative of the first height profile pattern and of the second height profile pattern.

According to some embodiments, data informative of the first height profile pattern and of the second height profile pattern includes label data comprising, for each given training image of a plurality of training images used to train the machine learning model, at least one segment of the given training image with a height profile pattern corresponding to the first height profile pattern, and at least another segment of the given training image with a height profile pattern corresponding to the second height profile pattern.

According to some embodiments, the data informative of the first height profile pattern and of the second height profile pattern have been obtained using three-dimensional data informative of one or more areas of one or more semiconductor specimens, wherein the three-dimensional data have been acquired by an examination tool.

According to some embodiments, the first height profile pattern and the second height profile pattern each correspond to a height profile pattern of a characteristic feature of a same element present in the inspection area.

According to some embodiments, at least one of the first segment or the second segment is informative of at least one of: a foot of an element present in the inspection area, a slope of an element present in the inspection area, an edge of an element present in the inspection area, a round edge of an element present in the inspection area, a top edge of an element present in the inspection area.

According to some embodiments, the machine learning model has been trained using, for each given area of a plurality of areas of at least one semiconductor specimen: a given image representative of 2D information of the given area acquired by an examination tool, given label data informative of a segmentation of the given image into at least a first segment S₁ and a second segment S₂, wherein the first segment S₁ corresponds to a first region of the given area which has a height profile corresponding to the first height profile pattern, and the second segment S₂ corresponds to a second region of the given area which has a height profile corresponding to the second height profile pattern.

According to some embodiments, for each given area, the given label data has been obtained using an image representative of 3D information of the given area acquired by an examination tool.

According to some embodiments, the image representative of 3D information of the given area has been acquired by an Atomic Force Microscope or a Scanning Transmission Electron Microscope.

According to some embodiments, the given label data has been obtained using a segmentation of the given image performed using the image representative of 3D information of the given area.

According to some embodiments, the system is configured to use at least one of the first segment S′₁ or the second segment S′₂ to determine metrology data informative of the inspection area.

In accordance with certain aspects of the presently disclosed subject matter, there is provided a method comprising, by one or more processing circuitries: obtaining, for each given area of a plurality of areas of a semiconductor specimen, a given image representative of 2D information of the given area, given label data informative of a segmentation of the given image into at least a first segment S₁ and a second segment S₂, wherein the first segment S₁ corresponds to a first region of the given area which has a first height profile pattern and the second segment S₂ corresponds to a second region of the given area which has a second height profile pattern, wherein the second height profile pattern is different from the first height profile pattern, and for each given area, feeding the given image and the given label data to a machine learning model for its training, wherein the machine learning model is operative, after its training, to segment an inspection image representative of 2D information of an inspection area into at least a first segment associated with a height profile corresponding to the first height profile pattern and a second segment associated with a height profile corresponding to the second height profile pattern.

According to some embodiments, the method comprises using the trained machine learning model to segment the inspection image representative of 2D information of the inspection area into a plurality of two-dimensional segments informative of different height profile patterns of the inspection area, without receiving 3D information on the inspection area.

According to some embodiments, the method comprises for each given area, obtaining a given second image representative of 3D information of the given area, wherein, for each given area, the given label data is determined using the given second image.

According to some embodiments, the method comprises, for each given area, obtaining a given second image representative of 3D information of the given area acquired by an Atomic Force Microscope or a Scanning Transmission Electron Microscope, wherein, for each given area, the given label data is determined using the given second image.

According to some embodiments, the segmentation of the given image is performed by the one or more processing circuitries using the given second image, data informative of the first height profile pattern and data informative of the second height profile pattern.

According to some embodiments, the segmentation of the given image is performed using a feedback of a user and the given second image.

According to some embodiments, the method comprises using the trained machine learning model to determine, for a given inspection image of a given inspection area, at least a first segment associated with a height profile corresponding to the first height profile pattern and a second segment associated with a height profile corresponding to the second height profile pattern.

According to some embodiments, the method comprises using at least one of the first segment or the second segment of the given inspection image to determine metrology data of the given inspection area.

In accordance with certain other of the presently disclosed subject matter, there is provided a non-transitory computer readable medium comprising instructions that, when executed by a processor, cause the processor to perform operations as described above.

In accordance with certain other of the presently disclosed subject matter, there is provided a non-transitory computer readable medium comprising instructions that, when executed by a processor, cause the processor to perform operations comprising: obtaining an inspection image representative of 2D information of an inspection area of a semiconductor specimen, and feeding the inspection image to a trained machine learning model operative to segment the inspection image into at least a first segment S′₁ and a second segment S′₂, wherein the first segment S′₁ corresponds to a first region of the inspection area which has a height profile pattern corresponding to a first height profile pattern, and the second segment S′₂ corresponds to a second region of the area which has a height profile pattern corresponding to a second height profile pattern, wherein the first height profile pattern is different from the second height profile pattern.

Among advantages of certain embodiments of the presently disclosed subject matter is to automatically provide three-dimensional information of a specimen based on a two-dimensional image of the specimen.

According to some embodiments, the solution uses a whole two-dimensional image of an area of a specimen in order to determine data informative of the height profile of the area, in contradiction to prior art methods which relied only on some specific points (topo-points). Therefore, the solution provides enriched information on the area of the specimen. Indeed, the whole image of the area can contain information of interest, and not only the topo-points.

According to some embodiments, the solution provides a wide range of information on the quality of a manufacturing process of an element of a semiconductor specimen.

According to some embodiments, the solution provides additional insights which can be used to improve the process window definition.

According to some embodiments, the solution provides pin-pointed feedback on various features of an element of a semiconductor specimen.

According to some embodiments, the solution enables determining enriched metrology data informative of a specimen.

According to some embodiments, the solution is efficient and automatic.

According to some embodiments, the solution provides to the manufacturer results of high value, which can assist them in R&D phase (e.g., to shorten correction cycles) and/or in High Volume Manufacturing (e.g., to fine tune the process window of various manufacturing and metrology tools).

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2A illustrates a generalized flow-chart of a method of segmenting a two-dimensional image into segments associated with different predefined height profile patterns.

FIG. 2B illustrates a non-limitative example of an inspection area in a specimen, for which an inspection image needs to be segmented using the method of FIG. 2A.

FIG. 3A illustrates a non-limitative example of a height profile of a slice of an element in a semiconductor specimen.

FIG. 3B illustrates a non-limitative example of a height profile of different slices of an element in a semiconductor specimen.

FIG. 3C illustrates a non-limitative example of an element (contact) in a semiconductor specimen.

FIG. 3D illustrates a non-limitative example of the output of the method of FIG. 2A.

FIG. 4 illustrates a generalized flow-chart of a method which uses the method of FIG. 2A to determine metrology data.

FIG. 5A illustrates a generalized flow-chart of a method of training the machine learning model used in the method of FIG. 2A.

FIG. 5B illustrates a non-limitative example of different areas of a specimen, wherein images of these areas, together with label data (segments), are fed to a machine learning model for its training.

FIG. 5C illustrates a generalized flow-chart of a method of generating label data associated with 2D images, based on 3D data provided by an examination tool.

FIG. 5D illustrates a non-limitative example of the training method of FIG. 5A.

FIG. 5E illustrates a non-limitative example of the segmentation performed by the machine learning model after its training.

### DETAILED DESCRIPTION OF EMBODIMENTS

In the following detailed description, numerous specific details are set forth in order to provide a thorough understanding of the disclosure. However, it will be understood by those skilled in the art that the presently disclosed subject matter may be practiced without these specific details. In other instances, well-known methods, procedures, components and circuits have not been described in detail so as not to obscure the presently disclosed subject matter.

Unless specifically stated otherwise, as apparent from the following discussions, it is appreciated that throughout the specification discussions utilizing terms such as “obtaining”, “feeding”, “segmenting”, “using”, “training”, “performing”, “determining”, or the like, refer to the action(s) and/or process(es) of a computer that manipulate and/or transform data into other data, said data represented as physical, such as electronic, quantities and/or said data representing the physical objects. The term “computer” should be expansively construed to cover any kind of hardware-based electronic device with data processing capabilities including, by way of non-limiting example, the system 103 and respective parts thereof disclosed in the present application.

The terms “non-transitory memory” and “non-transitory storage medium” used herein should be expansively construed to cover any volatile or non-volatile computer memory suitable to the presently disclosed subject matter.

The term “specimen” used in this specification should be expansively construed to cover any kind of wafer, masks, and other structures, combinations and/or parts thereof used for manufacturing semiconductor integrated circuits, magnetic heads, flat panel displays, and other semiconductor-fabricated articles.

The term “examination” used in this specification should be expansively construed to cover any kind of metrology-related operations, as well as operations related to detection and/or classification of defects in a specimen during its fabrication. Examination is provided by using non-destructive examination tools during or after manufacture of the specimen to be examined. By way of non-limiting example, the examination process can include runtime scanning (in a single or in multiple scans), sampling, reviewing, measuring, classifying and/or other operations provided with regard to the specimen or parts thereof using the same or different inspection tools. Likewise, examination can be provided prior to manufacture of the specimen to be examined, and can include, for example, generating an examination recipe(s) and/or other setup operations. It is noted that, unless specifically stated otherwise, the term “examination” or its derivatives used in this specification, are not limited with respect to resolution or size of an inspection area.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the following detailed description, numerous specific details are set forth in order to provide a thorough understanding of the methods and apparatus.

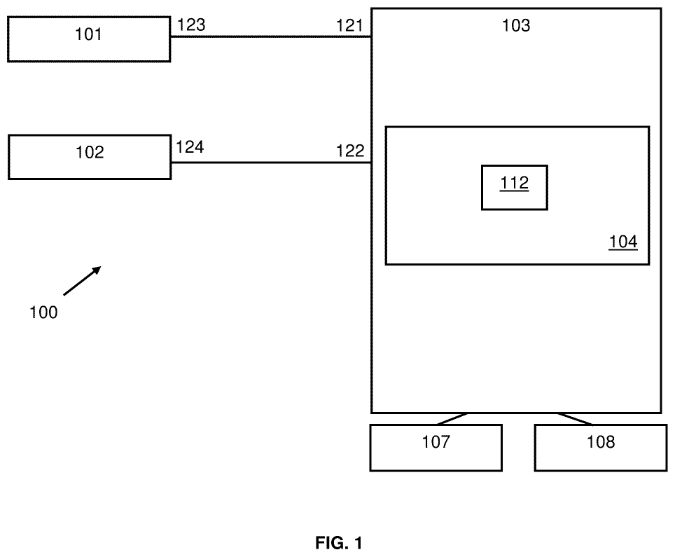

Bearing this in mind, attention is drawn to FIG. 1 illustrating a functional block diagram of an examination system in accordance with certain embodiments of the presently disclosed subject matter. The examination system 100 illustrated in FIG. 1 can be used for examination of a specimen (e.g. of a wafer and/or parts thereof) as part of the specimen fabrication process. The illustrated examination system 100 comprises computer-based system 103 capable of automatically determining metrology-related information using images obtained during specimen fabrication. System 103 can be operatively connected to one or more low-resolution examination tools 101 and/or one or more high-resolution examination tools 102 and/or other examination tools. The examination tools are configured to capture images and/or to review the captured image(s) and/or to enable or provide measurements related to the captured image(s).

System 103 includes one or more processing circuitries 104. The one or more processing circuitries 104 are configured to provide all processing necessary for operating the system 103, and, in particular, for processing the images captured by the examination tool(s).

The processor of the one or more processing circuitries 104 can be configured to execute one or more functional modules in accordance with computer-readable instructions implemented on a non-transitory computer-readable memory comprised in the one or more processing circuitries. Such functional modules are referred to hereinafter as comprised in the one or more processing circuitries. Functional modules comprised in the one or more processing circuitries 104 include a machine learning model 112, such as a deep neural network (DNN) 112. DNN 112 is configured to enable data processing for outputting application-related data based on the images of specimens.

By way of non-limiting example, the layers of DNN 112 can be organized in accordance with Convolutional Neural Network (CNN) architecture, Recurrent Neural Network architecture, Recursive Neural Networks architecture, Generative Adversarial Network (GAN) architecture, or otherwise. Optionally, at least some of the layers can be organized in a plurality of DNN sub-networks. Each layer of the DNN can include multiple basic computational elements (CE), typically referred to in the art as dimensions, neurons, or nodes.

Generally, computational elements of a given layer can be connected with CEs of a preceding layer and/or a subsequent layer. Each connection between a CE of a preceding layer and a CE of a subsequent layer is associated with a weighting value. A given CE can receive inputs from CEs of a previous layer via the respective connections, each given connection being associated with a weighting value which can be applied to the input of the given connection. The weighting values can determine the relative strength of the connections and thus the relative influence of the respective inputs on the output of the given CE. The given CE can be configured to compute an activation value (e.g., the weighted sum of the inputs) and further derive an output by applying an activation function to the computed activation. The activation function can be, for example, an identity function, a deterministic function (e.g., linear, sigmoid, threshold, or the like), a stochastic function, or other suitable function. The output from the given CE can be transmitted to CEs of a subsequent layer via the respective connections. Likewise, as above, each connection at the output of a CE can be associated with a weighting value which can be applied to the output of the CE prior to being received as an input of a CE of a subsequent layer. Further to the weighting values, there can be threshold values (including limiting functions) associated with the connections and CEs.

The weighting and/or threshold values of DNN 112 can be initially selected prior to training, and can be further iteratively adjusted or modified during training to achieve an optimal set of weighting and/or threshold values in a trained DNN. After each iteration, a difference (also called loss function) can be determined between the actual output produced by DNN 112 and the target output associated with the respective training set of data. The difference can be referred to as an error value. Training can be determined to be complete when a cost or loss function indicative of the error value is less than a predetermined value, or when a limited change in performance between iterations is achieved. Optionally, at least some of the DNN subnetworks (if any) can be trained separately, prior to training the entire DNN.

System 103 is configured to receive input data. Input data can include data 121, 122 (and/or derivatives thereof and/or metadata associated therewith) produced by the examination tools.

By way of non-limiting example, a specimen can be examined by one or more low-resolution examination machines 101 (e.g., an optical inspection system, low-resolution SEM, etc.). The resulting data (low-resolution image data 121), informative of low-resolution images of the specimen, can be transmitted—directly or via one or more intermediate systems—to system 103. Alternatively, or additionally, the specimen can be examined by a high-resolution machine 102 (e.g., a scanning electron microscope (SEM) and/or Atomic Force Microscopy (AFM)), etc.). The resulting data (high-resolution image data 122), informative of high-resolution images of the specimen, can be transmitted—directly or via one or more intermediate systems—to system 103.

According to some embodiments, the one or more processing circuitries 104 can send instructions to the low-resolution examination machine(s) 101 and/or to the high-resolution machine(s) 102.

It is noted that image data can be received and processed together with metadata (e.g., pixel size, text description of defect type, parameters of image capturing process, etc.) associated therewith.

Upon processing the input data (e.g. low-resolution image data and/or high-resolution image data, optionally together with other data as, for example, design data, synthetic data, etc.), system 103 can send the results (e.g. instruction-related data 123 and/or 124) to any of the examination tool(s), store the results (e.g. metrology measurements, etc.) in storage system 107, render the results via GUI 108 and/or send them to an external system (e.g. to YMS). A yield management system (YMS) in the context of semiconductor manufacturing is a data management, analysis, and tool system that collects data from the fab, especially during manufacturing ramp ups, and helps engineers find ways to improve yield. YMS helps semiconductor manufacturers and fabs manage high volumes of production analysis with fewer engineers. These systems analyze the yield data and generate reports. IMDs (Integrated Device Manufacturers), fabs, fabless semiconductor companies, and OSATs (Outsourced Semiconductor Assembly and Test) use YMSes.

Those versed in the art will readily appreciate that the teachings of the presently disclosed subject matter are not bound by the system illustrated in FIG. 1; equivalent and/or modified functionality can be consolidated or divided in another manner and can be implemented in any appropriate combination of software with firmware and/or hardware.

System 103 can be implemented as stand-alone computer(s) to be used in conjunction with the examination tools. Alternatively, the respective functions of the system can, at least partly, be integrated with one or more examination tools.

System 100 can be used to perform one or more of the methods described hereinafter.

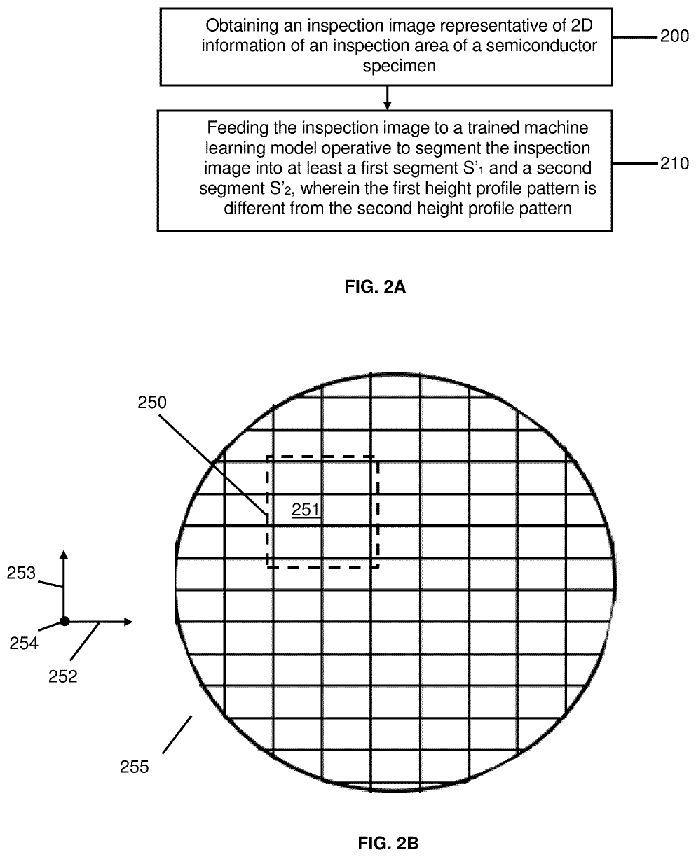

Attention is now drawn to FIGS. 2A and 2B.

The method of FIG. 2A includes obtaining (operation 200) an inspection image 250 of an inspection area 251 of a semiconductor specimen 255. The inspection image 250 is a two-dimensional image which is representative of 2D information of the inspection area 251 of the semiconductor specimen 255.

According to some embodiments, the inspection image 250 has been acquired by a scanning electron microscope (SEM). This is not limitative.

According to some embodiments, the inspection image 250 is obtained in run-time.

The method of FIG. 2A further includes feeding (operation 210) the inspection image 250 to a trained machine learning model (see e.g., reference 112 above). Embodiments for training of the machine learning model will be described hereinafter.

Note that, in some embodiments, the inspection image 250 provided by the examination tool (e.g., SEM) can be first processed (using e.g., image processing algorithm) before it is fed to the machine learning model.

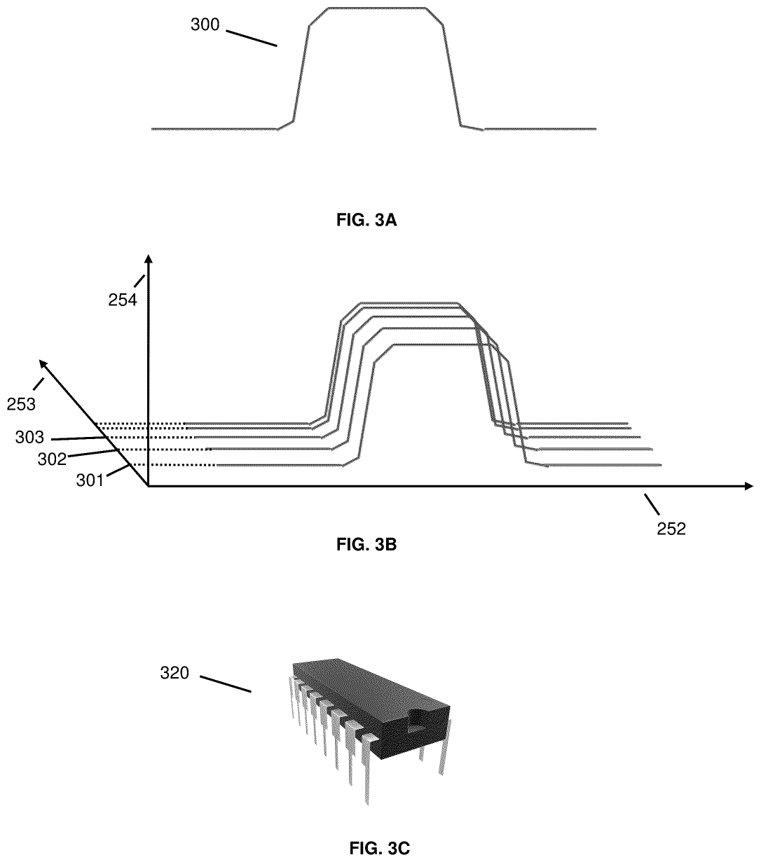

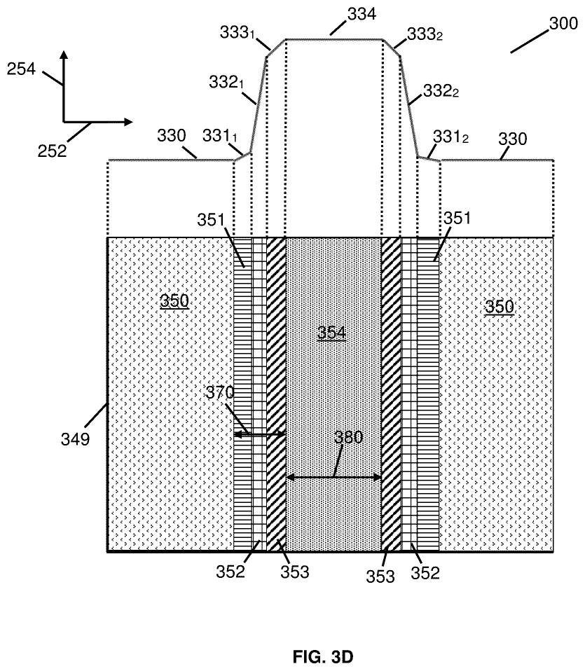

Assume for example that the inspection area 251 includes a given element (e.g., a contact—see reference 320 in FIG. 3C) which has a given three-dimensional shape. A non-limitative example of the height profile 300 of a given slice of a given element (this given element differs from the one depicted in reference 320) is depicted in FIG. 3A. Note that the slice is located in the plane X/Z, wherein X is an axis 252 located in the plane of the specimen, and Y is another axis 253 located in the plane of the specimen and orthogonal to the axis X, and Z is the vertical axis 254, which is orthogonal to axes X and Y.

Note that this height profile 300 is generally identical (or substantially identical) for different slices of the given element located at different coordinates 301, 302, 303 (etc.) along the Y axis 253 (see FIG. 3B). This is however not limitative.

The trained machine learning model 112 is operative to segment the inspection image 250 into at least two segments (or more than two segments). For example, the two segments include a first segment S′₁ and a second segment S′₂.

The first segment S′₁ corresponds to a first region of the inspection area 251 which has a height profile pattern corresponding to a first height profile pattern.

The second segment S′₂ corresponds to a second region of the inspection area 252 which has a height profile pattern corresponding to a second height profile pattern, wherein the first height profile pattern is different from the second height profile pattern.

In particular, although the inspection image 250 is a 2D image, the machine learning model 112 is able, by the virtue of its training (which is described hereinafter), to segment the inspection image 250 into different segments (two-dimensional segments) associated with different height profiles (3D information). In other words, it is possible to extract/determine 3D information based on a 2D image. The trained machine learning model is therefore operative to split the inspection image of the inspection area into a plurality of two-dimensional segments informative of different height profile patterns of the inspection area, based on 2D information of the inspection area and without receiving 3D information of the inspection area.

Note that the machine learning model 112 has been previously trained using data informative of the first height profile pattern and of the second height profile pattern. In particular, the machine learning model 112 has been previously trained to segment a 2D image of a specimen into a plurality of segments, wherein each segment is associated with a different pattern of height profile (corresponding respectively to the first height profile pattern and the second height profile pattern). This training can include feeding the machine learning model 112 with a plurality of training images, wherein each given training image is associated with a label which indicates a segment associated with a height profile pattern corresponding to the first height profile pattern and another segment associated with a height profile pattern corresponding to the second height profile pattern.

Note that the identification of the segments in the training images can rely on 3D data (height data) provided by an examination tool capable of determining 3D data in a specimen (non-limitative examples of this examination tool include an Atomic Force Microscope, or a Scanning Transmission Electron Microscope). This will be further discussed hereinafter. The 3D data can include the height profile of the specimen provided by an examination tool.

For example, assume that it is intended to train a machine learning model to identify, in a 2D image of a specimen, a first segment with a first height profile, and a second segment with a second height profile, different from the first height profile. The machine learning model can be trained using a training set of images in which each image of the training set is labelled with a label splitting the image into a first segment with a height profile corresponding to the first height profile, and a second segment with a height profile corresponding to the second height profile.

Note that the first height profile pattern and/or the second height profile pattern can each correspond to the height profile pattern of a characteristic feature of an element present in the inspection area. The characteristic feature can be a characteristic feature of the manufacturing process of the element. Non-limitative examples of characteristic features are provided below, such as the top edge of the element, the portion of the element with the steepest slope, a foot of the element, a slope of the element, an edge of the element, a round edge of the element, etc.

These characteristic features (features of interest) may be of interest for the manufacturer of the specimen, who can be interested to know the location and/or dimension(s) and/or shape of these features in the specimen.

According to some embodiments, the proposed solution enables, during run-time, an automatic determination of the segments corresponding to different features of interest (these features are of interest for the user of the solution, and/or for the manufacturer of the specimen) of a given structural element in a (2D) inspection image. Note that for each type of structural element, different features of interest can be identified. As a consequence, the proposed solution can automatically determine, in the 2D image, the width (or other geometrical parameters) of the different segments corresponding to the features of interest as defined by the user in the training phase. In other words, metrology data (e.g., Critical Dimension—CD) of the features of interest can be automatically extracted from these segments. Note that these metrology data are specifically tailored to the needs of the user, since they comply with the user definition of the features of interest during the training phase.

During a training phase, the proposed solution enables the user to define these specific features of interest for a given structural element. In particular, the user input enables identifying, in each training image of a training set of training images, the different segments of the training image that correspond to the features of interest, thereby obtaining a labelled training set of training images. For example, a first segment corresponds to the foot of a contact, a second segment corresponds to a certain part of the slope of this contact, etc. Each segment corresponds to a feature associated with a different height profile pattern. Note that the user can decide the definition of each feature (for example, he can define which part of the slope of the contact, which part of the foot of the contact, etc., corresponds to the feature of interest), and which features should be used to label the training images. The exact definition of each feature of interest can vary between users. Based on this training associated with these labels (as defined by the user), the trained machine learning model is able to identify automatically (during run-time examination) the features of interest of a given structural element, and to determine metrology data informative of these features.

FIG. 3D illustrates a non-limitative example of segmentation performed by the machine learning model 112, in which an inspection image 349 of an area of a specimen is segmented into four segments 350, 351, 352 and 354 (each informative of a different height profile pattern of a different feature of an element present in the area). Note that this is not limitative, and the segmentation can segment the image into a different number of segments, and/or based on different height profiles.

The first segment 350 corresponds to the bottom 330 of the height profile of the element. The height profile pattern of the first segment 350 is substantially flat. Note that in this non-limitative example, due to the symmetry of the height profile of the element, the image 349 contains twice the first segment 350.

The first segment 351 corresponds to the “foot” of the height profile of the element (transition between the bottom part of the element and the beginning or the end of the slope of the element). The height profile pattern of the first segment 351 has a given slope. Note that in this non-limitative example, due to the symmetry of the height profile, a first foot 3311 of the height profile has an ascendent slope (when moving along the X direction 252) and a second foot 3312 of the height profile has a descendent slope (when moving along the X direction 252). In this non-limitative example, the first foot 3311 and the second foot 3312 are classified into the same segment (first segment 351). This is not limitative, and, in some embodiments, they can be classified into two different segments.

The second segment 352 corresponds to the “slope” of the height profile of the given element. The height profile pattern of the second segment 352 has the steepest slope among all segments. Note that in this non-limitative example, due to the symmetry of the height profile, a first slope 3321 of the height profile is ascendent (when moving along the X direction 252) and a second slope 3322 of the height profile is descendent (when moving along the X direction 252). In this non-limitative example, the first slope 3321 and the second slope 3322 are classified into the same segment (second segment 352). This is not limitative, and, in some embodiments, they can be classified into two different segments.

The third segment 353 corresponds to a rounding portion of the top of the height profile of the given element (round edge). This corresponds to the transition between the steepest slope of the height profile and the top of the height profile of the given element. Note that in this non-limitative example, due to the symmetry of the height profile, a first rounding portion 3331 of the top of the height profile has an ascendent slope (when moving along the X direction 252) and a second rounding portion 3332 of the top of the height profile has an ascendent slope (when moving along the X direction 252). In this non-limitative example, the first rounding portion 3331 and the second rounding portion 3332 are classified into the same segment (third segment 353). This is not limitative, and, in some embodiments, they can be classified into two different segments.

The fourth segment 354 corresponds to the top 334 of the height profile of the given element. The height profile pattern of the fourth segment 354 is substantially flat. However, it differs from the height profile pattern of the first segment 350 in that the average height value is not the same between the two height profile patterns.

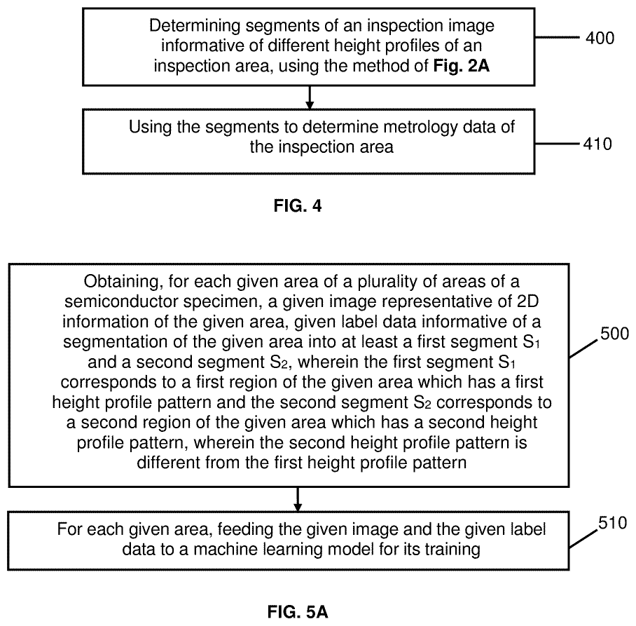

According to some embodiments, the segments provided by the machine learning model 112 based on the inspection image 349 are used to determine metrology data of the inspection area. This is illustrated in FIG. 4, which includes obtaining the segments based on the inspection image (operation 400), using the method of FIG. 2A. The method further includes using (operation 410) the segments to determine metrology data informative of the inspection area.

According to some embodiments, operation 410 can include determining a distance between two segments (e.g., each informative of a different feature), which is informative of a distance between two features of the element.

In a non-limitative example, in the segmented image 349 of FIG. 3D, the distance 370 (along the X axis) between the top edge 334 of the element (corresponding to segment 354) and the bottom 330 of the element (corresponding to segment 350) can be determined. This example is not limitative and various other applications can be implemented using the segmented image.

According to some embodiments, operation 410 can include determining a dimension of a segment (along the X axis) informative of a given feature of an element. This enables determining a dimension of the given feature of the element.

In a non-limitative example, in the segmented image of FIG. 3D, the dimension 380 of the segment 354 can be determined, which corresponds to the dimension of the top edge 334 of the element.

More generally, critical dimension (CD), distance between features, dimensions of features, shape of the element, etc. (or other metrology data) can be determined using the segmented image.

The metrology data determined using the segmented image can be used to detect defects in the manufacturing process of the specimen. For example, it can be detected that the dimension of a feature of the element does not match the expected dimension, or that the distance between two features of the element does not match the expected distance.

According to some examples, for each given structural element of a plurality of structural elements present in one or more inspection images of the specimen, the method uses the trained machine learning model to identify different segments corresponding to different features of interest of the given structural element. A set of segments is obtained (informative of the features of the plurality of structural elements).

The set of segments can be used to determine metrology data. The metrology data can be automatically determined and output (for example displayed) to the user. The method enables providing to the user, metrology data of a large number of structural elements, without requiring manual intervention of the user. The method can be performed (automatically) during run-time examination of the specimen. Run-time corresponds to a phase in which the specimen is examined by an examination tool, such as examination tool 101 and/or 102). Since the position of the features of interest of different structural elements has been determined in the inspection image(s), it is possible to determine width, CD, distance between features, or other metrology data, as explained hereinafter with reference to FIG. 4.

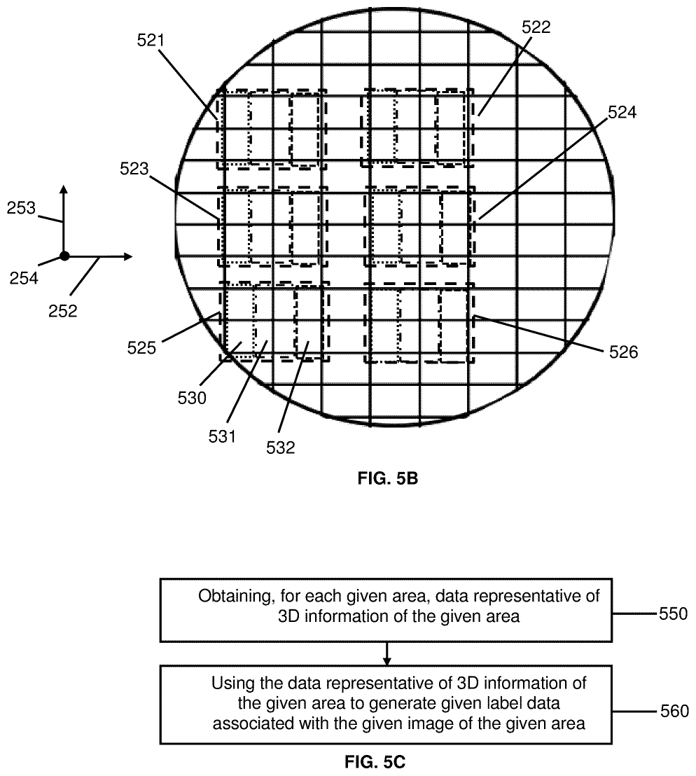

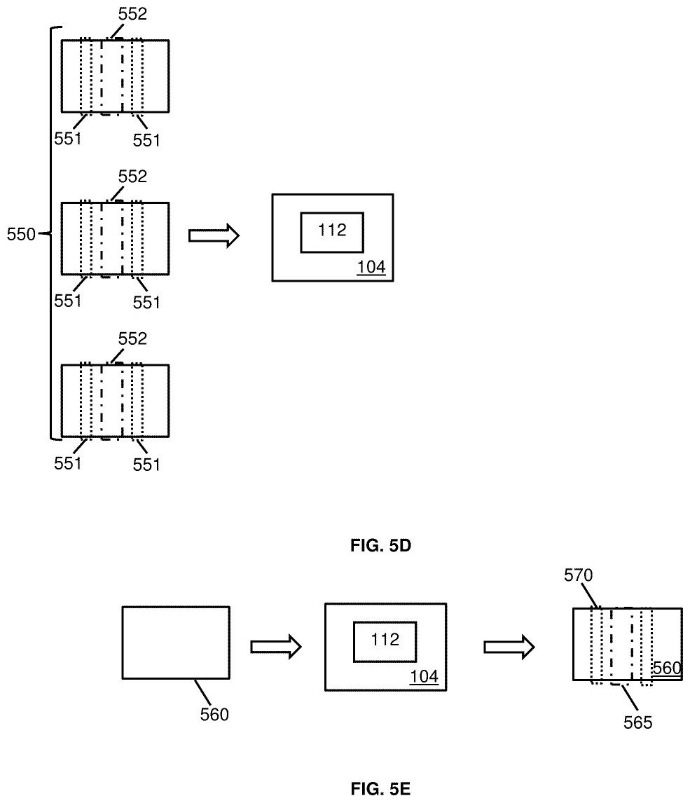

Attention is now drawn to FIGS. 5A and 5B, which depict a method of training the machine learning model used in the method of FIG. 2A.

The method includes obtaining (operation 500), for each given area of a plurality of areas (see 520, 521, 523, 524, 525, etc. in FIG. 5B) of a semiconductor specimen, a given image of the given area acquired by an examination tool. The given image is representative of 2D information of the given area. The examination tool can correspond e.g., to a SEM, which can be used to scan a plurality of areas of the specimen, in order to obtain a plurality of images of the plurality of areas. This is not limitative.

Note that the number of areas (see 520, 521, 523, 524, 525, etc.) can vary, depending on the application. In some embodiments, around hundred different areas can be acquired. This is not limitative. In some embodiments, the different areas contain the same element (e.g., contact). This is not limitative, and in some embodiments, at least some of the different areas can contain different elements (e.g., contact, gates, lines, etc.).

The method further includes obtaining (operation 510) given label data informative of a segmentation of the given image into at least a first segment S₁ and a second segment S₂ (or more).

The first segment S₁ corresponds to a first region of the given area which has a first height profile pattern.

The second segment S₂ corresponds to a second region of the given area which has a second height profile pattern, wherein the second height profile pattern is different from the first height profile pattern.

FIG. 5B illustrates an example in which each image of a given area (see training images 521, 522, 523, 524, 525, 526) is segmented similarly, into three different segments 530, 531 and 532. Each segment is associated with a different height profile pattern (which can be for example predefined by a user).

According to some embodiments, the segmentation of the given image (training image) into a first segment S₁ and a second segment S₂ (or more) can be performed by a user. The user can decide that the first segment is informative of a first region of interest, which has a particular pattern for its height profile, and that the second segment is informative of a second region of interest, which has a different particular pattern for its height profile. This segmentation can depend e.g., on considerations relative to the manufacturing process, on the particular height profile of the element, on metrology data that the user would like to obtain, etc.

Non-limitative examples of regions (labelled by the user) can include the top edge of the element, the portion of the element with the steepest slope, a foot of the element, a slope of the element, an edge of the element, a round edge of the element, a bottom part of the element, etc.

According to some embodiments, for each given area, the label data has been obtained using an image representative of 3D information (height data) of the given area acquired by an examination tool. This is illustrated in FIG. 5C. The method of FIG. 5C includes obtaining (operation 550), for each given area, data representative of 3D information of the given area. The data can correspond to a second image of the given area, which has been acquired by a second examination tool capable of determining 3D information (height data) of the specimen. According to some embodiments, the second examination tool is an Atomic Force Microscope, or a Scanning Transmission Electron Microscope. These examples are not limitative. In other words, each given area can be acquired by two different examination tools: the first examination tool (e.g., SEM) provides a 2D image of the given area, and the second examination tool (e.g., AFM or STEM) provides an image informative of the 3D height profile of the given area. The method of FIG. 5C further includes (operation 560) using the second image (which contains 3D information) of the given area to generate the given label data associated with the given image (training image) of the given area. Indeed, once the height profile of the given area is known (using the second image), a user can segment (supervised feedback) the given image of the given area into different segments, each associated with a different height profile pattern. The segmentation can be decided by the user, depending on the features of the element which are of interest for the user, and based on the 3D data obtained for the given area.

Note that the segmentation of the training images into segments corresponding to different height profile patterns (label data) can be performed, in some embodiments, using a computerized method.

For example, the different height profile patterns are defined by a user. For a given area of the specimen, an algorithm (e.g., a topography algorithm) receives the second image informative of the 3D height profile of the given area and uses it to segment the given image of the given area in accordance with these different height profile patterns.

According to some embodiments, for a given area of the specimen, a first machine learning model (different from the machine learning model 112 which has to be trained) can be fed with the second image informative of the 3D height profile of the given area and with the given image of the given area. The first machine learning model is operative to segment the given image into a plurality of two-dimensional segments, each informative of a different height profile. This first machine learning model can be previously trained (using unsupervised learning or supervised learning) to segment an image of an area into different regions, based on their height profile, and based on data informative of the 3D height profile of the area.

Once the set of 2D images has been obtained, together with the label data (indicative of the segments S₁ and S₂ associated with different height profile patterns), the method includes feeding (operation 510), for each given area, the given image and the given label data to the machine learning model (see reference 112) for its training. Note that the given 2D image may be pre-processed (using image processing algorithms(s)) before being fed to the machine learning model.

The machine learning model 112 is operative, after its training, to segment an inspection image of an inspection area into segments corresponding to the at least first segment S₁ and second segment S₂ (as used during the training phase).

According to some embodiments, the machine learning model 112 has been trained with training images of a semiconductor specimen which is comparable to the specimen for which inspection images are obtained during the prediction phase. In other words, the specimen(s) used during the training phase contain similar element(s) as the specimen used during the prediction phase.

Although the trained machine learning model receives only 2D data of the inspection area (without receiving 3D data of the inspection area, such as the height profile of the inspection area), it can split the inspection image into segments with different height profile patterns (3D data), corresponding to the height profile patterns used to define the label data.

In particular, the inspection image is segmented by the trained machine learning model into a first segment S′₁ and a second segment S′₂. The first segment S′₁ corresponds (substantial match) to the first segments S₁ of the training images of the training set. As a consequence, the height profile pattern of the first segment S′₁ corresponds to the first height profile patterns of the first segments S₁ of the training images. The second segment S′₂ corresponds (substantial match) to the second segments S₂ of the training images of the training set. As a consequence, the height profile pattern of the second segment S′₂ corresponds to the second height profile patterns of the second segments S₂ of the training images.

Note that a trained machine learning model is a model which attempts to achieve the best possible matching, although this matching may be non-perfect. Therefore, the first segment S′₁ may have a height profile which is not exactly identical to the first height profile pattern (as present in the training images). Similarly, the second segment S′₂ may have a height profile which is not exactly identical to the second height profile pattern (as present in the training images).

Depending on the definition of the segments provided in the label data during the training phase, the two-dimensional inspection image is segmented by the trained machine learning according to this definition.

A non-limitative example is provided in FIGS. 5D and 5E. Assume that the machine learning model is trained to segment a two-dimensional image of a contact into a first segment corresponding to the bottom part of a contact (flat height profile, with a low height), and a second segment corresponding to the region of the contact with the steepest slope. This can be obtained by training the machine learning model 112 with a training set 550 which includes a plurality of 2D training images of contacts (acquired e.g., by a SEM). Each 2D training image of the training set is associated with a label which indicates, in the 2D training image, a first segment 551 corresponding to the bottom part of the contact (reference 551 is present twice for each image since the contact is symmetric and includes two flat parts) and a second segment 552 corresponding to the region of the contact with the steepest slope. Note that the first segment and the second segment can be identified in each training image of the training set 550 using 3D data of the area present in the training image, as provided by an examination tool (such as an AFM).

When a new image 560 of a new contact is provided to the trained machine learning model 112 (see FIG. 5E), the trained machine learning model 112 automatically determines:
a first segment 565 corresponding to the first segments 551 of the label data of the training set 550—in particular, the first segment 565 is associated with a height profile corresponding to the flat height profile of the bottom part of a contact, as present in the first segments 551 of the label data of the training set 550 (as mentioned above, this correspondence is not necessarily perfect—the machine learning model 112 attempts to find a segment corresponding as much as possible to the first segments 551, thereby ensuring to have a corresponding height profile with a good matching with the height profile of the first segments 551 used for the training); and
a second segment 570 corresponding to the second segments 552 of the label data the training set 550—in particular, the second segment 570 is associated with a height profile corresponding to the steep slope of a contact, as present in the second segments 552 of the label data of the training set 550 (as mentioned above, this correspondence is not necessarily perfect—the machine learning model attempts to find a segment corresponding as much as possible to the second segments 552, thereby ensuring to have a corresponding height profile with a good matching with the height profile of the second segments 552 used for the training).

The terms “computer” or “computer-based system” should be expansively construed to include any kind of hardware-based electronic device with a data processing circuitry (e.g., digital signal processor (DSP), a GPU, a TPU, a field programmable gate array (FPGA), an application specific integrated circuit (ASIC), microcontroller, microprocessor etc.), including, by way of non-limiting example, the computer-based system 103 of FIG. 1 and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together. The one or more processors can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

It is to be noted that while the present disclosure refers to the processing circuitry 104 (or to the one or more processing circuitries 104) being configured to perform various functionalities and/or operations, the functionalities/operations can be performed by the one or more processors of the processing circuitry 104 in various ways. By way of example, the operations described hereinafter can be performed by a specific processor, or by a combination of processors. The operations described hereinafter can thus be performed by respective processors (or processor combinations) in the processing circuitry 104, while, optionally, at least some of these operations may be performed by the same processor. The present disclosure should not be limited to be construed as one single processor always performing all the operations.

In embodiments of the presently disclosed subject matter, fewer, more, and/or different stages than those shown in the methods of FIGS. 2A, 4, 5A and 5C may be executed. In embodiments of the presently disclosed subject matter, one or more stages illustrated in the methods of FIGS. 2A, 4, 5A and 5C may be executed in a different order, and/or one or more groups of stages may be executed simultaneously.

It is to be understood that the invention is not limited in its application to the details set forth in the description contained herein or illustrated in the drawings.

It will also be understood that the system according to the invention may be, at least partly, implemented on a suitably programmed computer. Likewise, the invention contemplates a computer program being readable by a computer for executing the method of the invention. The invention further contemplates a non-transitory computer-readable memory tangibly embodying a program of instructions executable by the computer for executing the method of the invention.

The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

What is claimed is:

1. A system comprising one or more processing circuitries configured to:
obtain an inspection image representative of 2D information of an inspection area of a semiconductor specimen, and
feed the inspection image to a trained machine learning model operative to segment the inspection image into at least a first segment S′₁ and a second segment S′₂, wherein:
the first segment S′₁ corresponds to a first region of the inspection area which has a height profile pattern corresponding to a first height profile pattern, and
the second segment S′₂ corresponds to a second region of the area which has a height profile pattern corresponding to a second height profile pattern,
wherein the first height profile pattern is different from the second height profile pattern,
wherein the first segment S′₁ corresponds to a first feature of a given structural element present in the inspection area, and the second segment S′₂ corresponds to a second different feature of the same given structural element.

2. The system of claim 1, configured to, during run-time examination of the specimen, use the trained machine learning model to determine, in the inspection image, a plurality of segments corresponding to different features of interest of the same given structural element present in the inspection area.

3. The system of claim 2, wherein the features of interest, or data informative thereof, have been used in training of the machine learning model.

4. The system of claim 1, configured to:
for each given structural element of a plurality of structural elements present in the inspection area, use the trained machine learning model to determine segments of the inspection image corresponding to different features of interest of said given structural element, thereby obtaining a set of segments, and
use the set of segments to determine metrology data informative of the plurality of the structural elements.

5. The system of claim 1, wherein the trained machine learning model is operative to segment the inspection image representative of 2D information of the inspection area into a plurality of two-dimensional segments informative of different height profile patterns of the inspection area, without receiving 3D information on the inspection area.

6. The system of claim 1, wherein the machine learning model has been trained using training images, wherein each training image has been segmented into a first segment S₁ corresponding to the first segment S′₁ of the inspection image and a second segment S₂ corresponding to the second segment S′₂ of the inspection image.

7. The system of claim 1, wherein the machine learning model has been trained using data informative of the first height profile pattern and of the second height profile pattern.

8. The system of claim 4, wherein data informative of the first height profile pattern and of the second height profile pattern includes label data comprising, for each given training image of a plurality of training images used to train the machine learning model, at least one segment of the given training image with a height profile pattern corresponding to the first height profile pattern, and at least another segment of the given training image with a height profile pattern corresponding to the second height profile pattern.

9. The system of claim 4, wherein the data informative of the first height profile pattern and of the second height profile pattern have been obtained using three-dimensional data informative of one or more areas of one or more semiconductor specimens, wherein the three-dimensional data have been acquired by an examination tool.

10. The system of claim 1, wherein the first height profile pattern and the second height profile pattern each correspond to a height profile pattern of a characteristic feature of said same given structural element present in the inspection area.

11. The system of claim 1, wherein at least one of the first segment or the second segment is informative of at least one of: a foot of an element present in the inspection area, a slope of an element present in the inspection area, an edge of an element present in the inspection area, a round edge of an element present in the inspection area, a top edge of an element present in the inspection area.

12. The system of claim 1, wherein the machine learning model has been trained using, for each given area of a plurality of areas of at least one semiconductor specimen:
a given image representative of 2D information of the given area acquired by an examination tool,
given label data informative of a segmentation of the given image into at least a first segment S₁ and a second segment S₂, wherein:
the first segment S₁ corresponds to a first region of the given area which has a height profile corresponding to the first height profile pattern, and
the second segment S₂ corresponds to a second region of the given area which has a height profile corresponding to the second height profile pattern.

13. The system of claim 12, wherein, for each given area, the given label data has been obtained using an image representative of 3D information of the given area acquired by an examination tool.

14. The system of claim 13, wherein the image representative of 3D information of the given area has been acquired by an Atomic Force Microscope or a Scanning Transmission Electron Microscope.

15. The system of claim 1, configured to use at least one of the first segment S′₁ or the second segment S′₂ to determine metrology data informative of the inspection area.

16. A method comprising, by one or more processing circuitries:
obtaining, for each given area of a plurality of areas of a semiconductor specimen:
a given image representative of 2D information of the given area,
given label data informative of a segmentation of the given image into at least a first segment S₁ and a second segment S₂, wherein:
the first segment S₁ corresponds to a first region of the given area which has a first height profile pattern, and
the second segment S₂ corresponds to a second region of the given area which has a second height profile pattern, wherein the second height profile pattern is different from the first height profile pattern,
wherein the first segment S₁ corresponds to a first feature of a given structural element present in the given area, and the second segment S₂ corresponds to a second different feature of the same given structural element,
for each given area, feeding the given image and the given label data to a machine learning model for its training,
wherein the machine learning model is operative, after its training, to segment an inspection image representative of 2D information of an inspection area into at least a first segment associated with a height profile corresponding to the first height profile pattern and a second segment associated with a height profile corresponding to the second height profile pattern.

17. The method of claim 16, comprising using the trained machine learning model to segment the inspection image representative of 2D information of the inspection area into a plurality of two-dimensional segments informative of different height profile patterns of the inspection area, without receiving 3D information on the inspection area.

18. The method of claim 16, comprising performing (i) or (ii):
(i) for each given area, obtaining a given second image representative of 3D information of the given area, wherein, for each given area, the given label data is determined using the given second image, or
(ii) for each given area, obtaining a given second image representative of 3D information of the given area acquired by an Atomic Force Microscope or a Scanning Transmission Electron Microscope, wherein, for each given area, the given label data is determined using the given second image.

19. The method of claim 16, wherein:
the segmentation of the given image is performed by the one or more processing circuitries using the given second image, data informative of the first height profile pattern and data informative of the second height profile pattern, or
the segmentation of the given image is performed using a feedback of a user and the given second image.

20. A non-transitory computer readable medium comprising instructions that, when executed by one or more processing circuitries, cause the one or more processing circuitries to perform:
obtaining an inspection image representative of 2D information of an inspection area of a semiconductor specimen, and
feeding the inspection image to a trained machine learning model operative to segment the inspection image into at least a first segment S′₁ and a second segment S′₂, wherein:
the first segment S′₁ corresponds to a first region of the inspection area which has a height profile pattern corresponding to a first height profile pattern, and
the second segment S′₂ corresponds to a second region of the area which has a height profile pattern corresponding to a second height profile pattern,
wherein the first height profile pattern is different from the second height profile pattern,
wherein the first segment S′₁ corresponds to a first feature of a given structural element present in the inspection area, and the second segment S′₂ corresponds to a second different feature of the same given structural element.
